(19) United States
(12) Patent Application Publication
(10) Pub. No.: US 2011/0156190 A1
(43) Pub. Date: Jun. 30, 2011

(54) ELECTRONIC COMPONENT

(75) Inventor: Ryuji Mori, Kirishima (JP)

(73) Assignee: KYOCERA CORPORATION, Kyoto-shi (JP)

(21) Appl. No.: 12/977,695

(22) Filed: Dec. 23, 2010

(30) Foreign Application Priority Data
Dec. 24, 2009 (JP) 2009-292213

(51) Int. Cl. H01L 23/26; H01L 31/02

(52) U.S. Cl. 257/433; 257/682; 257/E23.137; 257/E31.11

(57) ABSTRACT

An electronic component includes a base member comprising a main surface, a cap member on the base member, a first concave portion between the main surface and the cap member, a second concave portion on the main surface, an element on the main surface and above the second concave portion, and a getter member in the second concave portion and under the element. The second concave portion, when observed from a planar view, includes a first opening portion overlapping the element and a second opening portion not overlapping the element.

### CROSS-REFERENCE TO RELATED APPLICATION

The present application claims priority under 35 U.S.C. §119 to Japanese Patent Application No. 2009-292213, filed on Dec. 24, 2009, entitled “ELECTRONIC COMPONENT, PACKAGE AND INFRARED SENSOR”. The content of which is incorporated by reference herein in its entirety.

### FIELD

Embodiments of the present disclosure relate generally to electronic component, and more particularly relate to an electronic component comprising a device therein.

### BACKGROUND

Some electronic components may comprise one or more elements sealed therein such as an acceleration sensor element, an infrared sensor element, a gyro sensor element, or a crystal oscillator and the like. The electronic component may comprise a getter member therein to reduce gases therein so that the element would show the innate characteristics.

The electronic component is required to have low height (or size reduction). Therefore, there is a need for an electronic component having low height while having a getter member therein.

### SUMMARY

An electronic component with a first concave portion and a second concave portion is disclosure. The second concave portion comprises a getter which is located under an element with a space between the getter and the element.

In an embodiment, an electronic component includes a base member comprising a main surface, a cap member on the base member, a first concave portion between the main surface and the cap member, a second concave portion on the main surface, an element on the main surface and above the second concave portion, and a getter member in the second concave portion and under the element. The second concave portion, when observed from a planar view, includes a first opening portion overlapping the element and a second opening portion not overlapping the element.

In another embodiment, a package includes a base member, a first concave portion on the base member, a main surface of the base member on the first concave portion, an element on the main surface, a second concave portion on the main surface under the element, and a getter member in the second concave portion and under the element. The second concave portion, when observed from a planar view, comprises a first opening portion and a second opening portion. The first opening portion overlaps the element while the second opening portion does not overlap the element.

In yet another embodiment, an infrared sensor includes a substrate, the electronic component on the substrate, and a terminal operable to provide power to the element.

### BRIEF DESCRIPTION OF THE DRAWINGS

Embodiments of the present disclosure are hereinafter described in conjunction with the following figures, wherein like numerals denote like elements. The figures are provided for illustration and depict exemplary embodiments of the present disclosure. The figures are provided to facilitate understanding of the present disclosure without limiting the breadth, scope, scale, or applicability of the present disclosure. The drawings are not necessarily made to scale.

FIG. 1 is an illustration of a cross-sectional view of an electronic component according to an embodiment of the present disclosure.

FIG. 2 is an illustration of a cross-sectional view of an electronic component according to an embodiment of the present disclosure.

FIG. 3 is an illustration of a cross-sectional view of an electronic component according to an embodiment of the present disclosure.

FIGS. 4A to 4C are illustrations of exemplary cross-sectional views of the electronic component along with IV-IV in FIG. 3.

FIG. 5 is an illustration of a cross-sectional view of an IR sensor according to an embodiment of the disclosure.

### DETAILED DESCRIPTION

The following description is presented to enable a person of ordinary skill in the art to make and use the embodiments of the disclosure. The following detailed description is exemplary in nature and is not intended to limit the disclosure or the application and uses of the embodiments of the disclosure. Descriptions of specific devices, techniques, and applications are provided only as examples. Modifications to the examples described herein will be readily apparent to those of ordinary skill in the art, and the general principles defined herein may be applied to other examples and applications without departing from the spirit and scope of the disclosure. Furthermore, there is no intention to be bound by any expressed or implied theory presented in the preceding technical field, background, brief summary or the following detailed description. The present disclosure should be accorded scope consistent with the claims, and not limited to the examples described and shown herein.

Embodiments of the disclosure are described herein in the context of one practical non-limiting application, namely, an electronic component such as a package. Embodiments of the disclosure, however, are not limited to such packages, and the techniques described herein may be utilized in other applications. For example, embodiments may be applicable to acceleration sensor device, infrared sensor device, gyro sensor device, crystal oscillator, and the like.

As would be apparent to one of ordinary skill in the art after reading this description, these are merely examples and the embodiments of the disclosure are not limited to operating in accordance with these examples. Other embodiments may be utilized and structural changes may be made without departing from the scope of the exemplary embodiments of the present disclosure.

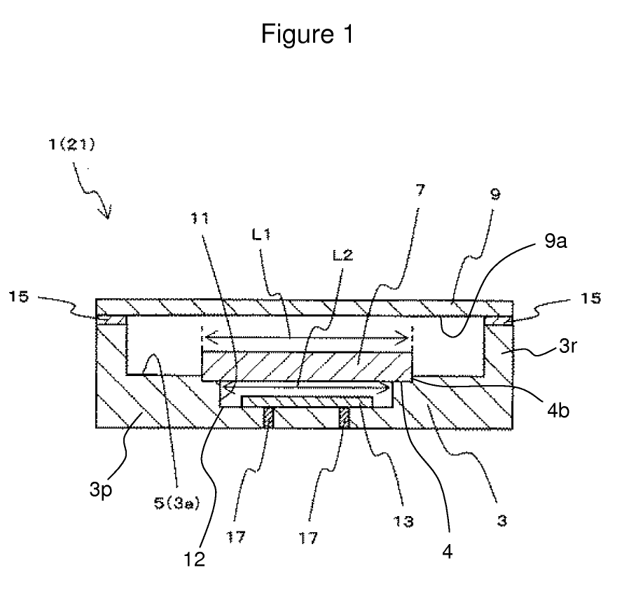

As shown in FIG. 1, an electronic component 1 comprises: a base member 3 that comprises a first concave portion 5 on a main surface 3a thereof; an element 7 that is disposed in the first concave portion 5; and a cap member 9 that is disposed on the base member 3 so as to seal the first concave portion 5.

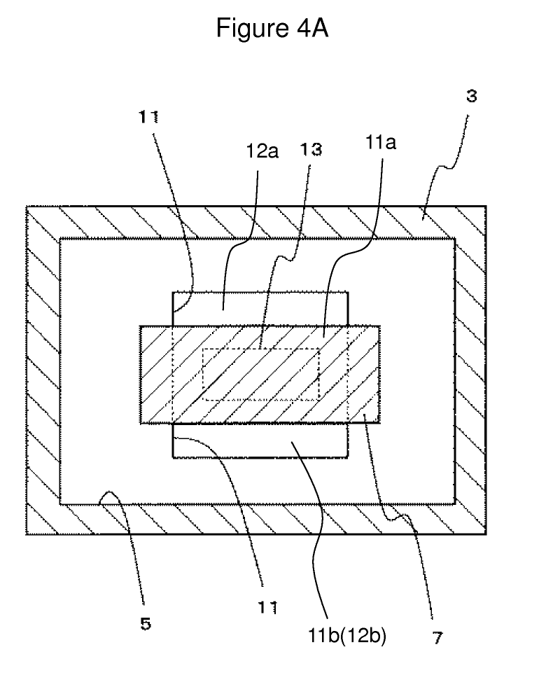

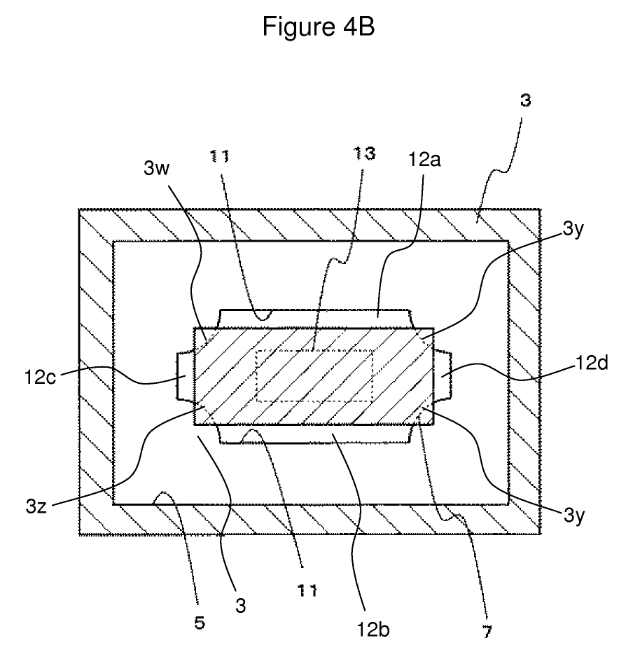

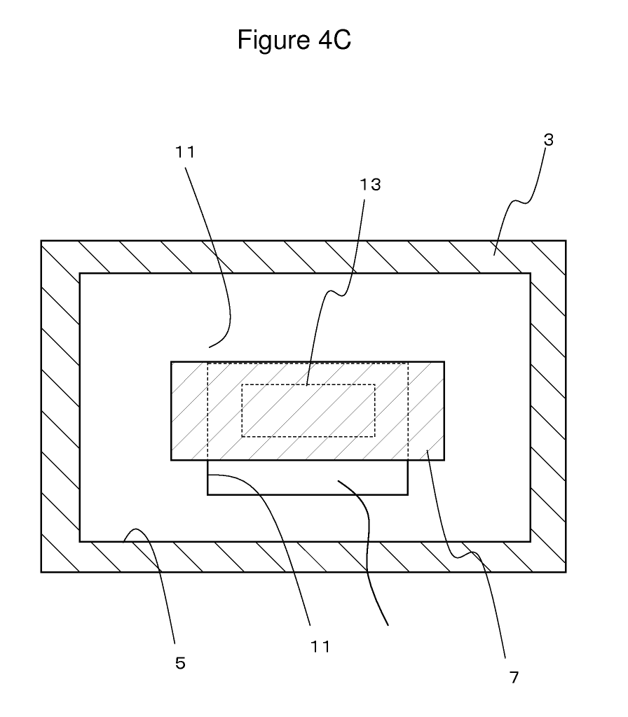

The base member 3 may have a plate shape. Alternatively, the base member 3 may comprise a plate portion 3p and a rim portion 3b. The base member 3 comprises a second concave portion 11 at a place that is located under the element 7. The element 7 may not cover the entire second concave portion. For example and without limitation, when the second concave portion 11 is observed from top (in a planar view), an opening of the second concave portion 11 comprises a first portion (11a in FIG. 4) that is covered by the element 7 and a second portion (11b in FIG. 4) that is not covered the element 7. In the second concave portion 11, the base member 3 is partially separated from the element 7. In the electronic component 1 according to this embodiment, the second concave portion 11 comprises a getter member 13 therein.

In the electronic component 1 according to the present embodiment, since the element 7 is in the concave portion of the base member 3, the electronic component 1 can have a reduced height, thereby achieving size reduction. Since the second concave portion 11 is located under the element 7, the base member 3 partially contacts the element 7. The base member 3 comprises a cut-off portion 4, which contacts the element 7, at an edge around the second concave portion 11. That is, the base member 3 and the element 7 have a reduced contact area. Therefore gas molecules generated from the base member 3 in a manufacturing process of the electronic component 1 and in use can have less effect on the element 7. In addition, the electronic component 1 according to the present embodiment can have less influence of heat from outside of the electric component 1 on the element 7 by reducing heat transmission from the electronic component 1 to the element 7 than the known electric component.

The second concave portion 11 comprises the getter member 13, which has larger surface area than those on an inner surface of a cap member of known electric components, on the bottom surface 12 thereof. Accordingly, the getter member can absorb more gas molecules. The first portion of the second concave portion 11 is located around the element 7. That is, the second concave portion 11 is connected to the first concave portion 5. Therefore, the getter member 13 can absorb not only gas molecules in the second concave portion 11 but also gas molecules in the first concave portion 5. Therefore, gas molecules generated from the base member 3 in a manufacturing process of the electronic component 1 and in use can have less effect on the element 7.

The second concave portion 11 comprises getter member 13 therein, thereby reducing the pressure in the first concave portion and the second concave portion of the electronic component 1, which are a sealed space sealed by the cap member 9 because the getter member 13 absorbs gas molecules inside the electronic component 1. The gas molecules in the first concave portion and the second concave portion may include gas that is generated from members, such as the base member 3 and the cap member 9, constituting the electronic component 1 in manufacturing process of the electronic component 1 or in use and vapors such as H₂O that is trapped in the manufacturing process.

In other words, a package 21 may comprise the electronic component 1. Therefore, such package may have lower internal pressure than known packages.

The cap member 9 on the base member 3 can seal the first concave portion 5 and the element 7 that is disposed in the first concave portion 5.

The electronic component 1 comprises the base member 3 that has the first concave portion 5 on the main surface 3a. It can be used as the electronic component 1 by disposing the element 7 that is described below in this first concave portion 5 and sealing the first concave portion 5 with the cap member 9.

The base member 3 may comprise an insulating member. For example but without limitation, the insulating member comprises a member that comprises a ceramic material as a main component such as an alumina ceramics, a mullite ceramics and the like.

The element 7 may comprise elements such as an acceleration sensor element, an infrared sensor element, a gyro sensor element, a crystal oscillator and the like. For example, when an infrared sensor is manufactured, the infrared sensor element may be disposed in the first concave portion 5 as the element 7. In the same manner, when an acceleration sensor is manufactured, the acceleration sensor element may be disposed in the first concave portion 5 as the element 7.

The cap member 9 may comprise insulating members such as a ceramics or a glass that the bonding surface is metalized, a metal member, a silicon member. The ceramics member may comprise a member that comprises a ceramic material as a main component such as an alumina ceramics and a mullite ceramics. The cap member 9 may have any shape if the cap member can seal the first concave portion 5. For example and without limitation, the cap member can have a plate shape, “U” shape in a cross section or the like.

The cap member 9 is bonded with the base member 3 via a bonding member 15. The bonding member 15 can seal the space between the base member 3 and the cap member 9 by bonding the base member 3 and the cap member 9. The bonding member may comprise Au, Ag, Zn, Sn, Cu and alloys thereof as a main component.

In a cross section perpendicular to the main surface 3a, the base member 3 comprises the second concave portion 11 at a portion that is located under the element 7. Additionally, in the second concave portion 11, the base member 3 is partially separated from the element 7. Therefore, a contact area between the base member 3 and the element 7 can be reduced; hence, in the portion that the element 7 contacts the base member 3, the influence of heat on the element 7 can be reduced by suppressing the heat that is transferred from the base member 3 to the element 7.

The second concave portion 11 may have a depth greater than the thickness of the getter member 13 by 0.1 mm or more. This is because the possibility of the contact between the element 7 and the getter member 13 can be reduced by making the depth of the second concave portion 11 deeper than the thickness of the getter member 13 by 0.1 mm or more, even if an irregularity of approximately 10 to 20 μm is created on the surface of the getter member 13.

The second concave portion 11 may also have a width greater than the width of the getter member 13 by 0.1 mm or more. This is because the possibility of the contact between an inner wall surface of the second concave portion 11 and the getter member 13 can be reduced by making the width of the second concave portion 11 wider than the width of the getter member 13 by 0.1 mm or more, even if a position on which the getter member 13 is arranged is displaced. Therefore, the uniformity of activity of the getter member 13 may be uniformly active during heating.

In an embodiment, the base member 3 can have a dimension of 5 to 50 mm in longitudinal length, 5 to 50 mm in lateral length, and 0.5 to 5 mm in thickness as well as the first concave portion 5 has a dimension of 3.5 to 48 mm in longitudinal length, 3.5 to 48 mm in lateral length, and 0.2 to 4.5 mm in thickness, the second concave portion 11 may have a dimension of 2.5 to 46 mm in longitudinal length, 2.5 to 46 mm in lateral length, and 0.1 to 4 mm in depth. For example but without limitation, the base member 3 can have a dimension of 15 mm in longitudinal length, 15 mm in lateral length, and 2 mm in thickness as well as the first concave portion 5 has a dimension of 10 mm in longitudinal length, 10 mm in lateral length, and 1 mm in thickness, the second concave portion 11 can have a dimension of 8 mm in longitudinal length, 8 mm in lateral length, and 0.5 mm in depth.

In an embodiment, in one cross section perpendicular to the main surface 3a, a width L1 of the element 7 in a direction parallel to the main surface 3a is greater than a width L2 of the second concave portion 11 in a direction parallel to the main surface 3a. Accordingly, the base member 3 can stably support the element 7 while reducing the bonding area between the base member 3 and the element 7. Therefore less displacement of the element 7 may occur. In the embodiment shown in FIG. 1, in a cross section perpendicular to the main surface 3a, both ends of the element 7 is supported by the base member 3.

In this case, as shown in FIG. 1, the element 7 may be supported by the base member 3 at not only the cut-off part portion 4 but also at least a part of the side surface 4b. Accordingly, less displacement of the element 7 can occur, allowing the base member 3 to support the element 7 more stably.

The getter member 13 may comprise a chemically active member. In an embodiment, a metal powder that comprises Ti, Zr, Fe, and V as main components may be mixed with an organic solvent such as a cellulose nitrate resin, an ethyl cellulose resin and the like to make a conductive paste. Then, the conductive paste, which will become the getter member 13, is printed on a desired position of the second concave portion 11 with a thickness by a printing method such as a screen printing method, followed by heating the resultant conductive paste at 200° C. to 300° C. in an inert gas atmosphere (for example, an argon atmosphere) or in a vacuum atmosphere so as to vaporize and remove the organic solvent from the getter member. Alternatively, the getter member may be formed by a typical vapor deposition method, a sputtering method or a method in which a getter member 22 formed into a tablet is adhered. The getter member 13 may be 2.4 to 45 mm in longitudinal length, 2.4 to 45 mm lateral length, and 0.5 μm to 1 mm in thickness. The getter member 13 having thickness of 0.5 μm or more can stably absorb gases. The getter member 13 having thickness of 1.0 μm or less can suppress an excessive increase in a thermal capacity, thereby enhancing the uniformity of activity of the getter member 13 during heating the getter member 13.

If a film such as an oxide film that is a compound formed by a chemical reaction with adsorbed gas molecules on the surface of the getter member 13, the getter member 13 have a less absorbing power. However, the compound can be diffused into inside the getter member 13 by heating the getter member 13. Accordingly, a new active surface can appear on the surface of the getter member 13 and therefore, the getter member 13 can improve the absorbing power. The getter member 13 can be heated to 250 to 500° C. in order to form the new active surface efficiently on the getter member 13.

The getter member 13 may be coupled to a terminal 17 and the power can be supplied form the external circuit to the getter member 13 via the terminal 17 in order to heat the getter member 13. Accordingly, power can be supplied to the getter member 13 even after the first concave portion 5 is sealed with a cap member 8. In this case, the getter member 13 can be arranged on the surface of a metal plate. The metal plate may comprise a nichrome. For example and without limitation, the getter member 13 can be prepared by forming a metal or a compound thereof including Ti, Zr, Fe and/or V as a main component on the surface of a nichrome plate by a method such as a printing method, an evaporation method, a sputtering method, or the like. The getter member 13 can be activated by applying current of approximately 2 to 5 A to the getter member 13 for 15 to 30 minutes so as to increase and keep a temperature of the getter member 13 to 250 to 500° C.

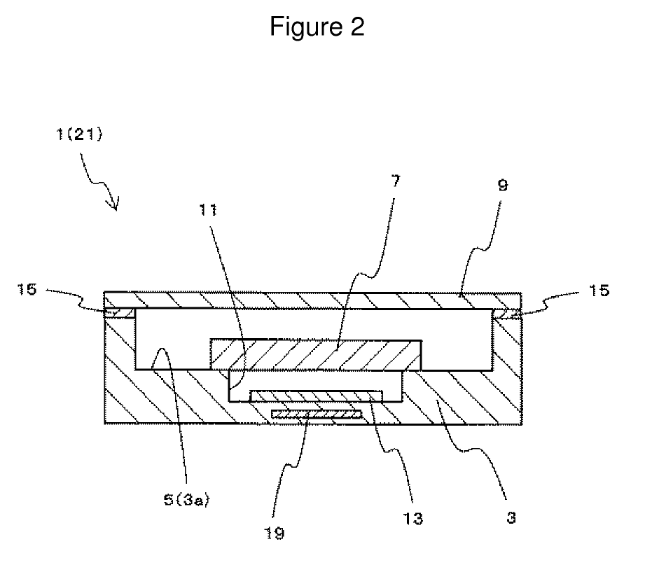

FIG. 2 is an illustration of a cross-sectional view of an electronic component according to an embodiment of the present disclosure. As compared to the embodiment shown in FIG. 1, the electronic component 1 shown in FIG. 2 further comprises a heater 19 for heating the getter member 13. The heater 19 may be located inside the base member 3 and under the getter member 13. The heater 19 can reduce the inner pressure of the first concave portion 5 and the second concave portion 11 of the electronic component 1.

The heater 19 may be prepared as follows: a tungsten metal powder is mixed with an organic solvent such as a cellulose nitrate resin, an ethyl cellulose resin, or the like to make a conductive paste. The conductive paste, which will become the heater 19, is printed on the base member 3 by a printing method such as a screen printing method. However, the heater 19 can have the almost same dimension as that of the getter member and have a thickness of 10 to 50 μm in a planar view. Such heater 19 can have, for example, a meander-shaped pattern, and the like to generate more heat with the same area. The heater 19 can generate heat by applying power thereto. The getter member 13 can be activated by applying current of, for example, approximately 2 to 5 A to the heater 19 for 15 to 30 minutes so as to heat the getter member 13 at 250 to 500° C. If the base member 3 and the cap member 9 are heated, gas may be generated from those members and the pressure in the electronic component 1 may be increased. Therefore, the characteristics of the element 7 may be decreased. In addition, the element 7 may have decrease in the characteristics of the element 7 at an elevated temperature.

As a result, the getter member 13 is heated efficiently while avoiding overheating of the base member 3, the cap member 9, and the element 7. Accordingly, the getter member 13 can have a new active surface at the surface thereof while reducing generation of gas from the base member 3 and the cap member 9.

In particular, in a cross section of the base member 3 that is perpendicular to the main surface 3a, the heater 19 may be located within a width in a direction parallel to the main surface 3a of the getter member 13. Accordingly, heat generated by the heater 19 can be transferred to the getter member 13 sufficiently but heat transfer from the getter member 13 to the element 7 can further be suppressed.

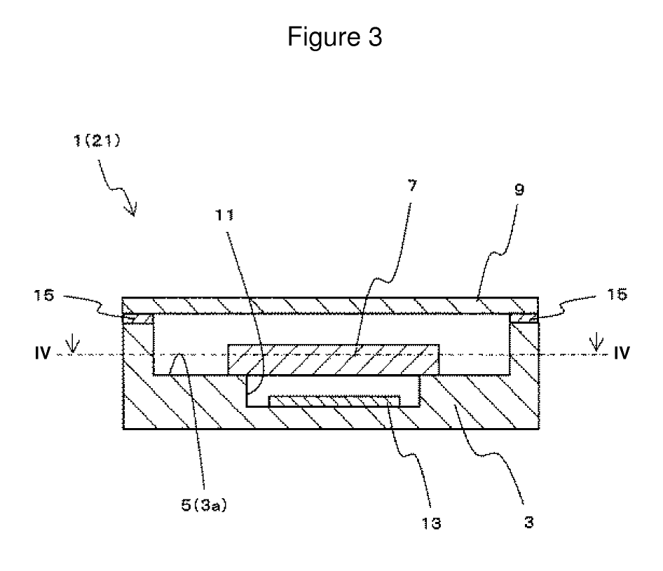

FIG. 3 is an illustration of a cross-sectional view of an electronic component according to an embodiment of the present disclosure. FIGS. 4A to 4C are illustrations of exemplary cross-sectional views of the electronic component along with IV-IV in FIG. 3.

An electronic component 1 shown in FIGS. 3 and 4A to 4C comprises, a first opening portion that is located under the element 7 and a second opening portion that is located around the element 7, when the second concave portion 11 on which the element 7 is arranged is observed from a planar view. The second opening portion may comprise, for example and without limitation, a plurality of openings. Accordingly, gas molecules in the first concave portion 5 and gas molecules in the second concave portion 11 can be easily circulated; hence, the getter member 13 can absorb more efficiently the gas molecules in the first concave portion 5 and the gas molecules in the second concave portion 11.

Specifically, as shown in FIG. 4A, the opening of the second concave portion 11 comprises an opening 12a and an opening 12b at both sides of the element 7. Accordingly, gas molecules in the first concave portion 5 can be absorbed more efficiently into the getter member 13. The second concave portion 11 comprises four second opening portions 12a and 12b.

The element 7 has a rectangular shape in a planar view. The four corners of the element 7 are supported by the base member 3. The opening of the second concave portion 11 comprises openings 12a, 12b, 12c and 12d along four sides of the element 7. Accordingly, gas molecules in the first concave portion 5 can be absorbed more efficiently into the getter member 13.

As shown in FIG. 4B, four support portions 3w, 3x, 3y and 3z for supporting the element 7 has a curve shape, and the element 7 is bonded with the support portions 3w to 3z of the base member 3. In this case, the stress that is applied on the bonding surface between the element 7 and the base member 3 can be relaxed. The second concave portion 11 comprises four second opening portions 12a, 12b, 12c and 12d.

As shown in FIG. 4C, the second concave portion 11 comprises only one second opening portion 12a.

A method of manufacturing the electronic component of the present invention is described in detail below.

The base member 3 that has the first concave portion 5 and the second concave portion 11 on the main surface 3a is prepared. Specifically, ceramic green sheets comprising ceramic materials such as an alumina ceramics and a mullite ceramics as a main component are laminated to make a laminated body so as to have the first concave portion 5 and the second concave portion 11. Then, the resultant laminated body is fired to form the base member 3. In an embodiment, the first concave portion 5 and the second concave portion 11 are formed on the ceramic green sheet in advance. Alternatively, the first concave portion 5 and the second concave portion 11 may be formed after laminating and baking the ceramic green sheet.

Next, the element 7 is disposed on the bottom surface of the first concave portion 5 so as to be located on the second concave portion 11.

Next, the cap member 9 is disposed on the top surface of the base member 3 so as to seal the first concave portion 5.

The base member 3 may be connected with the cap member 9 using the bonding member 15. The bonding member 15 may comprise a cladded member, a preformed member, and a paste-like member, for example. The bonding member 15 may be disposed on the bonding surface between the base member 3 and the cap member 9 by metallization or may be disposed on the abovementioned bonding surface between the base member 3 and the cap member 9 by a printing method using the paste-like bonding member 15. Then, the base member 3 is bonded with the cap member 9 via the bonding member 15 by heating and melting the bonding member 15.

The first concave portion 5 is sealed with using the cap member 9 at a pressure lower than the normal pressure (1 atm). More specifically, the first concave portion 5 can be sealed at a reduced pressure by using a decompressor such as a vacuum chamber. In this case, the pressure may be set appropriately depending on a required pressure inside the electronic component 1 by the decompressor. Accordingly, the pressure inside the electronic component 1 can be reduced from the normal pressure.

The electronic component 1 according to embodiments of this disclosure can be manufactured through the abovementioned manufacturing method.

In the abovementioned process of manufacturing the electronic component 1, a process of heating the getter member 13 may be included. As a result, the getter member 13 can have a new active surface on the surface thereof, thereby absorbing more gas molecules.

For example and without limitation, the getter member 13 may be heated for activation when the cap member 9 and the base member 3 are bonded. In this bonding process, when the base member 3 and the cap member 9 are heated, gas is released from the base member 3, cap member 9, and the bonding member 15. Therefore, activation of the getter member 13 in the process of bonding the cap member 9 with the base member 3 can reduce the pressure inside the electronic component 1.

The infrared sensor according to an embodiment of the present disclosure is now described below.

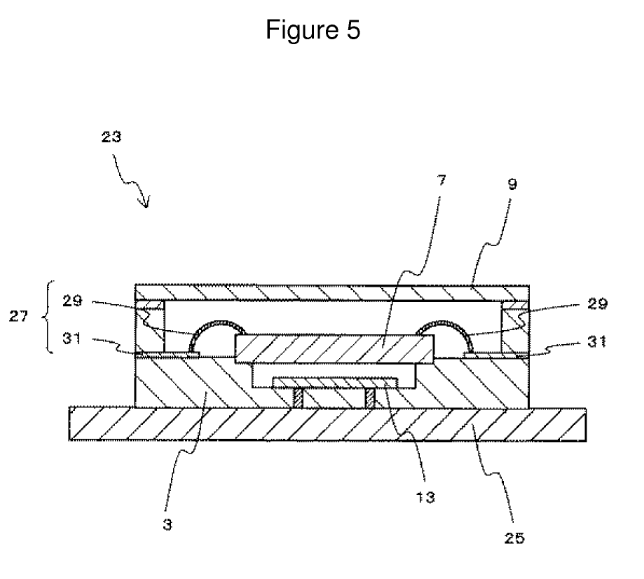

FIG. 5 is an illustration of a cross-sectional view of an infrared sensor 23 according to an embodiment of the disclosure. The infrared sensor 23 comprises a substrate 25, the electronic component 1 located on the substrate 25, and an energizing member 27 for providing power to the element 7 of the electronic component 1. The electronic component 1 is represented by the abovementioned embodiment. In the present embodiment, the element 7 may be an infrared sensor element 7.

As for the infrared sensor 23, because the electronic component 1 further comprises the getter member 13 that is disposed in the second concave portion 11, the influence of gas molecules, which are generated from the base member 3 during manufacturing and using the electronic component 1, on the infrared sensor element can be reduced. Therefore, the infrared sensor 23 can maintain the performance, thereby showing high performance even in long-term use.

The substrate 25 may comprise any materials as long as the substrate 25 can support the electronic component 1. Specifically, the substrate 25 may comprise a ceramic plate, a resin plate, a metal plate and the like.

The energizing member 27 comprises an extraction electrode 31 and a wiring conductor 29. The extraction electrode 31 may be extracted from the first concave portion 5 to the outer surface of the infrared sensor 23. The wiring conductor 29 may electrically connect the extraction electrode 31 with the infrared sensor element 7.

While at least one exemplary embodiment has been presented in the foregoing detailed description, the present disclosure is not limited to the above-described embodiment or embodiments. Variations may be apparent to those skilled in the art. In carrying out the present disclosure, various modifications, combinations, sub-combinations and alterations may occur in regard to the elements of the above-described embodiment insofar as they are within the technical scope of the present disclosure or the equivalents thereof. The exemplary embodiment or exemplary embodiments are examples, and are not intended to limit the scope, applicability, or configuration of the disclosure in any way. Rather, the foregoing detailed description will provide those skilled in the art with a template for implementing the exemplary embodiment or exemplary embodiments. It should be understood that various changes can be made in the function and arrangement of elements without departing from the scope of the disclosure as set forth in the appended claims and the legal equivalents thereof. Furthermore, although embodiments of the present disclosure have been described with reference to the accompanying drawings, it is to be noted that changes and modifications may be apparent to those skilled in the art. Such changes and modifications are to be understood as being comprised within the scope of the present disclosure as defined by the claims.

Terms and phrases used in this document, and variations hereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the present disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent. The term “about” when referring to a numerical value or range is intended to encompass values resulting from experimental error that can occur when taking measurements.

1. An electronic component comprising:
a base member comprising a main surface;
a cap member on the base member;
a first concave portion between the main surface and the cap member;
a second concave portion on the main surface;
an element on the main surface and above the second concave portion; and
a getter member in the second concave portion and under the element, wherein the second concave portion, when observed from a planar view, comprises:
a first opening portion overlapping the element; and
a second opening portion not overlapping the element.

2. The electronic component according to claim 1, further comprising
a terminal electrically connected to the getter member and operable to provide power to the getter member for heating.

3. The electronic component according to claim 1, further comprising
a heater inside the base member and under the getter member.

4. The electronic component according to claim 1, wherein the second opening portion comprises a plurality of opening portions.

5. A package comprising:
a base member;
a first concave portion on the base member;
a main surface of the base member on the first concave portion;
an element on the main surface;
a second concave portion on the main surface under the element;
a getter member in the second concave portion and under the element, wherein the second concave portion, when observed from a planar view, comprises:
a first opening portion overlapping the element; and
a second opening portion not overlapping the element.

6. The package according to claim 5, further comprising
a terminal electrically connected to the getter member and operable to provide power to the getter member for heating.

7. The package according to claim 5, further comprising
a heater inside the base member overlapping the getter member.

8. The package according to claim 5, wherein the second opening portion comprises a plurality of opening portions.

9. An infrared sensor comprising:
a substrate;
the electronic component according to claim 1 on the substrate; and
a terminal operable to provide power to the element.

10. The infrared sensor according to claim 9, further comprising
a heater inside the base member overlapping the getter member.

11. The infrared sensor according to claim 9, wherein the second opening portion comprises a plurality of opening portions.
